(19) United States
(12) Patent Application Publication
(10) Pub. No.: US 2021/0050280 A1
(43) Pub. Date: Feb. 18, 2021

(54) ELECTRONIC DEVICE AND METHOD FOR MANUFACTURING ELECTRONIC DEVICE

(71) Applicant: Panasonic Intellectual Property Management Co., Ltd., Osaka (JP)

(72) Inventors: AKIHITO KONISHI, Hokkaido (JP); RYOSUKE USUI, Hokkaido (JP); NORIHIRO KAWAMURA, Hokkaido (JP)

(21) Appl. No.: 17/050,429

(22) PCT Filed: May 13, 2019
(86) PCT No.: PCT/JP2019/018947

§ 371 Date: Oct. 23, 2020

(30) Foreign Application Priority Data
Jun. 28, 2018 (JP) 2018-122586

(51) Int. Cl. H01L 23/373; H01L 21/48

(52) U.S. Cl. CPC H01L 23/3737; H01L 21/4814

(57) ABSTRACT

A highly reliable electronic device that efficiently dissipates generated heat and a method for manufacturing the electronic device are provided. The electronic device includes mount board, heat generating component mounted on mount board, pressing component provided above heat generating component, and film provided between heat generating component and pressing component. Further, liquid heat conductive material is provided between heat generating component and film and between pressing component and graphite-based carbonaceous film. Film contains graphite-based carbon and is compressed to predetermined compressibility by pressing component.

### TECHNICAL FIELD

The present disclosure relates to an electronic device with improved heat dissipation efficiency from a semiconductor element mounted on a wiring member and a method for manufacturing the electronic device.

### BACKGROUND ART

Since it has become possible to flow a large current in a semiconductor element, heat generation may become extremely large, and measures against heat dissipation are important. Therefore, heat conductive grease is provided between a heat generating component and a heat dissipating material, and heat is transmitted from the heat generating component to the heat dissipating material through the heat conductive grease.

It should be noted that, for example, PTL 1 is known as a prior art document containing information related to this technique.

### CITATION LIST

### Patent Literature

PTL 1: Unexamined Japanese Patent Publication No. 2018-26458

### SUMMARY OF THE INVENTION

However, when heat conductive grease is used, there is a possibility of pump-out in which the heat conductive grease is discharged to outside due to thermal expansion associated with heat generation, deterioration of the heat conducting grease itself, or the like. Further, thermal conductivity of the heat conductive grease is deteriorated if the heat conductive grease contains bubbles, and heat dissipation of a heat dissipating material may be deteriorated.

In order to solve the above problems, an electronic device according to the present disclosure includes: a mount board; a heat generating component provided on this mount board; a pressing component provided above the heat generating component; and a film provided between the heat generating component and the pressing component. Further, the electronic device includes a liquid heat conductive material provided between the heat generating component and the film and between the pressing component and the film. The film contains graphite-based carbon and is compressed to predetermined compressibility by pressure received from the pressing component.

By configuring the electronic device according to the present disclosure as described above, it is possible to obtain a highly reliable electronic device that efficiently dissipates generated heat.

### BRIEF DESCRIPTION OF DRAWINGS

FIG. 1 is a sectional view of an electronic device according to an exemplary embodiment of the present disclosure.

FIG. 2 is a sectional view of a vicinity of a film in the electronic device shown in FIG. 1.

FIG. 3 is a sectional view illustrating a method for manufacturing the electronic device according to the exemplary embodiment of the present disclosure.

### DESCRIPTION OF EMBODIMENT

Hereinafter, an electronic device according to an exemplary embodiment of the present disclosure will be described with reference to the drawings.

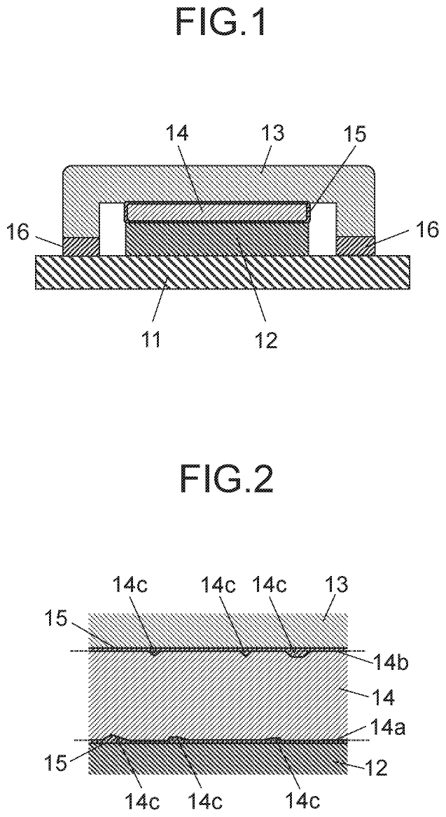

FIG. 1 is a sectional view of the electronic device according to the exemplary embodiment of the present disclosure. Further, FIG. 2 is a sectional view of a vicinity of film 14 in the electronic device shown in FIG. 1.

In FIG. 1, a semiconductor element is flip-chip mounted on mount board 11 as heat generating component 12. This heat generating component 12 has a shape of a rectangle with a size of about 9 mm×14 mm and has a height of about 0.4 mm. A lid made of copper and having a thickness of about 3 mm is provided as pressing component 13 above heat generating component 12. Film 14 is provided on heat generating component 12. Film 14 is pressed by pressing component 13 and adhered to mount board 11. As a result, film 14 is in a compressed state. Further, oil made of perfluoropolyether is provided as heat conductive material 15 between heat generating component 12 and film 14 and between pressing component 13 and film 14.

Film 14 is made of a material having high thermal conductivity. In the present exemplary embodiment, graphite-based carbon is used as the material having high thermal conductivity. In other words, film 14 is made of graphite-based carbon.

Here, graphite-based carbon will be briefly described. Graphite and diamond are known as carbon as crystals. Graphite-based carbon is carbon having graphite as a main member. Examples of methods for producing graphite-based carbon include a method for simply processing natural graphite and a method for pyrolyzing organic matter such as a polyimide film. In particular, graphite-based carbon obtained by pyrolyzing organic matter is called pyrolytic graphite-based carbon.

Film 14 has first surface 14a facing heat generating component 12 and second surface 14b facing the pressing component. Here, void 14c is formed in a vicinity including an interface between heat generating component 12 and film 14 (lower dotted line in FIG. 2) and in a vicinity including an interface between pressing component 13 and film 14 (upper dotted line in FIG. 2). Void 14c is filled with heat conductive material 15. Here, when void 14c is generated, thermal conductivity is deteriorated at that portion, so that porosity of this void needs to be less than or equal to 5%. Further, it is more desirable to set the porosity to less than or equal to 2%.

Note that the porosity will be described here. A single void or a plurality of voids may be formed between heat generating component 12 and film 14 or between pressing component 13 and film 14. In particular, when film 14 contains pyrolytic graphite-based carbon, a single void or a plurality of voids is formed between heat generating component 12 and film 14 or between pressing component 13 and film 14. In this case, for the void(s) formed between heat generating component 12 and film 14, a ratio of a total area of the void(s) when the void(s) is/are projected onto first surface 14a to an area of first surface 14a (an entire area of first surface 14a) is called the porosity. Similarly, a single void or a plurality of voids is found between pressing component 13 and film 14, and a ratio of a total area of the void(s) when the void(s) is/are projected onto second surface 14b to an area of second surface 14b (an entire area of second surface 14b) is called the porosity.

Film 14 has an initial thickness of about 100 μm and a compressibility of about 35% when a pressure of 100 kPa is applied. Here, the compressibility is expressed as a percentage of a value of (T0−T1)/T0, where T0 is an initial thickness and T1 is a thickness when a pressure of 100 kPa is applied. A pressure of about 200 kPa is applied by pressing component 13 using such film 14 made of graphite-based carbon. Thus, the thickness of film 14 with pressing component 13 mounted is about 50 μm. As described above, by using film 14 having a compressibility of more than or equal to 30% when a pressure of 100 kPa is applied, it is possible to obtain an electronic device having good heat dissipation.

It is desirable that the material of film 14 contain pyrolytic graphite-based carbon. In particular, it is desirable that film 14 be made of pyrolytic graphite-based carbon. Pyrolytic graphite-based carbon is excellent in thermal conductivity in a plane direction. Therefore, even if heat generation of heat generating component 12 is localized, generated heat can be quickly diffused in the plane direction and transmitted to pressing component 13. Thus, the heat can be efficiently dissipated.

As heat conductive material 15, perfluoropolyether having a kinematic viscosity at 25° C. of about 10 cSt is used. By using this heat conductive material 15 and applying a pressure of about 200 kPa by pressing component 13, a thickness of heat conductive material 15 with pressing component 13 mounted is about 2 μm. By applying the pressure in this way, film 14 and heat conductive material 15 can be compressed, unevenness of heat generating component 12, film 14, and pressing component 13 can be filled, and thermal resistance can be greatly reduced.

As heat conductive material 15, it is desirable to use one having a kinematic viscosity at 25° C. ranging from 2 cSt to 15 cSt inclusive. When the kinematic viscosity is less than 2 cSt, it is difficult to apply a sufficient heat conductive material to film 14, and for example, there is a possibility that a cavity will occur between heat generating component 12 and film 14 or between pressing component 13 and film 14. On the other hand, when the kinematic viscosity exceeds 15 cSt, even if film 14 has a defect such as a void, it will be difficult to detect the defect. Note that the cavity is a kind of the void.

Further, it is desirable that an end surface of film 14 be covered with heat conductive material 15. Thus, it is possible to prevent graphite powder from falling from film 14 and improve reliability.

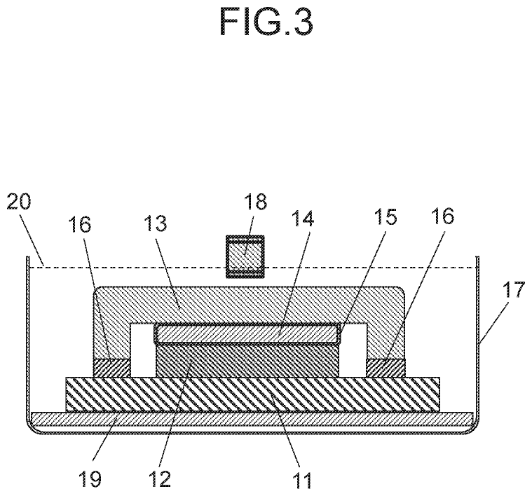

Next, a method for manufacturing the electronic device according to the exemplary embodiment of the present disclosure will be described with reference to FIG. 3.

First, a semiconductor element is flip-chip mounted on mount board 11 as heat generating component 12. Next, film 14 cut into a predetermined shape is dipped in oil made of perfluoropolyether and disposed on heat generating component 12. Film 14 is made of pyrolytic graphite-based carbon having a thickness of about 100 μm, and has a compressibility of about 35% when a pressure of 100 kPa is applied. The shape of film 14 is identical to a shape of an upper surface of heat generating component 12. Further, the oil used is low-molecular-weight perfluoropolyether having a kinematic viscosity at 25° C. of about 10 cSt, which is heat conductive material 15.

A lid made of copper and having a thickness of about 3 mm is disposed on film 14 as pressing component 13. Pressing component 13 applies pressure in a direction of mount board 11 and fixes film 14 with adhesive 16 while compressing film 14. By applying a pressure of about 200 kPa, film 14 has a thickness of about 50 μm, and heat conductive material 15 has a thickness of about 2 μm.

Next, as shown in FIG. 3, mount board 11 on which pressing component 13 is mounted is immersed in water tub 17 and placed on evaluation stage 19. Ultrasonic probe 18 is disposed between water surface 20 and pressing component 13, and ultrasonic probe 18 emits an ultrasonic wave of about 50 MHz from pressing component 13 side to detect a reflected wave of the ultrasonic wave. Information of the reflected wave obtained by scanning ultrasonic probe 18 in a plane direction of heat generating component 12 is converted into image information. Thus, it is possible to detect a void between heat generating component 12 and film 14 and between pressing component 13 and film 14, or a defect of film 14. If a single void or a plurality of voids is found between heat generating component 12 and film 14 and a total area of the void(s) projected onto first surface 14a exceeds 5% of an area of first surface 14a, the electronic device can be removed as a defective product. Further, if a single void or a plurality of voids is found between pressing component 13 and film 14 and the void/voids having a total area of the void(s) projected onto second surface 14b exceeds 5% of an area of second surface 14b is/are found, the electronic device can be removed as a defective product.

Thus, it is possible to fill unevenness of heat generating component 12, film 14, and pressing component 13 with the heat conductive material, and it is possible to obtain an electronic device that is excellent in heat dissipation and has no cavities between heat generating component 12 and film 14 and between pressing component 13 and film 14.

Note that a material of film 14 used in the present exemplary embodiment is graphite-based carbon, but expanded graphite using natural graphite can also be used.

Note that a printed circuit board can be used as mount board 11, for example. As heat generating component 12, it is possible to use a resistance element, a capacitor, or the like other than the semiconductor element.

### INDUSTRIAL APPLICABILITY

In an electronic device and a method for manufacturing the electronic device according to the present disclosure, a highly reliable electronic device that efficiently dissipates generated heat can be obtained, and is industrially useful.

### REFERENCE MARKS IN THE DRAWINGS

11: mount board

12: heat generating component

13: pressing component

14: film

14a: first surface

14b: second surface

14c: void

15: heat conductive material

16: adhesive

17: water tub

18: ultrasonic probe

19: evaluation stage

20: water surface

1. An electronic device comprising:
a mount board;
a heat generating component provided on the mount board;
a pressing component provided above the heat generating component;
a film provided between the heat generating component and the pressing component; and
a liquid heat conductive material provided between the heat generating component and the film and between the pressing component and the film,
wherein the film contains graphite-based carbon and is compressed to have a predetermined compressibility by pressure received from the pressing component.

2. The electronic device according to claim 1, wherein
the film has a first surface facing the heat generating component and a second surface facing the pressing component, and
a porosity of a void formed at an interface between the heat generating component and the film is less than or equal to 5%, and porosity of a void formed at an interface between the pressing component and the film is less than or equal to 5%.

3. The electronic device according to claim 1, wherein the predetermined compressibility is more than or equal to 30% at a pressure of 100 kPa.

4. The electronic device according to claim 1, wherein the heat conductive material has a kinematic viscosity at 25° C. ranging from 2 cSt to 15cSt inclusive.

5. A method for manufacturing an electronic device, the method comprising:
mounting a heat generating component on a mount board;
arranging a film having graphite-based carbon on the heat generating component, the film being coated with a liquid heat conductive material;
arranging a pressing component on the film and compressing the film; and
by emitting an ultrasonic wave from a side of the pressing component and detecting a reflected wave of the ultrasonic wave, examining a void between the heat generating component and the film and between the pressing component and the film.

6. The method for manufacturing the electronic device according to claim 5, wherein
the film has a first surface facing the heat generating component and a second surface facing the pressing component, and
an area of a void formed at an interface between the heat generating component and the film is less than or equal to 5% of an area of the first surface, and an area of a void formed at an interface between the pressing component and the film is less than or equal to 5% of an area of the second surface.
